(19) United States
(12) Patent Application Publication
(10) Pub. No.: US 2003/0231470 A1
(43) Pub. Date: Dec. 18, 2003

(54) Electrical device, in particular for a motor vehicle

(76) Inventor: Henryk Frenzel, Regensburg (DE)

Correspondence Address: Baker Botts L.L.P., One Shell Plaza, 910 Louisiana, Houston, TX, 77002-4995, US

(21) Appl. No.: 10/457,937

(22) Filed: Jun. 10, 2003

(30) Foreign Application Priority Data
Jun. 12, 2002 (DE) 102 26 136.9

(51) Int. Cl. H05K 7/20

(52) U.S. Cl. 361/715

(57) ABSTRACT

The invention relates to an electrical device for that features a cup-shaped housing to accept a circuit carrier (4) with a front side insertion opening. The circuit carrier (4) features a connector (5). the insertion opening is sealed by a sealing part (2 and/or 3) that features a cutout for the connector (5). The sealing part (2 and/or 3) is connected by a mechanical hinge to one side of the insertion opening of the housing. To seal the insertion opening the sealing part (2 and/or 3) is hinged over the insertion opening, whereby location elements (8) engage into cutouts (9) of the lower part of the housing (1). The cup-shaped housing of the electrical device in accordance with the invention thus only has one open side.

### PRIORITY

This application claims foreign priority of the German application DE 10226136.9 filed on Jun. 12, 2002.

### TECHNICAL FIELD OF THE INVENTION

The invention relates to an electrical device, in particular for a motor vehicle.

### BACKGROUND OF THE INVENTION

A control unit for a motor vehicle is known from disclosure document DE 196 12 063 A1 that features a housing open on two opposite sides. A circuit board with a molded plug is pushed through an insertion opening into the housing. The side of the housing located opposite the insertion opening features a one-piece plug receptacle connected to the housing. Only after the plug is in its end position can the insertion opening be sealed with a captive cover on the housing, attached by a film hinge for example.

The object held towards the connector has the disadvantage that the housing has openings on two sides and therefore dust and water can penetrate from both sides into the housing. The housing is thus not protected in any mounting position without additional seals against intrusion of dust and water.

Furthermore assembly is relatively difficult since the housing is overspecified. With the known controller the overspecification is produced by the printed circuit board guide and the opening through which the connector must be routed. One the one hand the printed circuit board must be adequately fixed on the side opposite the connector, on the other hand, the connector mechanically connected to the printed circuit board must meet the other side of the housing through the cutout. If the printed circuit board is not adequately fixed vibrations can damage the circuit arrangement. The solder points can be subjected to such loads by the overspecification that solder point breaks can occur during the life of the device.

A further known electrical device (DE 197 05 173 A1) is an electrical device that features a cup-shaped housing with an insertion opening for a circuit carrier that is sealed by a seal that is stamped out in one piece with the connector part.

### SUMMARY OF THE INVENTION

The disadvantage of this electrical device lies in the fact that, one hand two tools are required to manufacture the housing parts, on the other hand low-cost standard connectors cannot be used or the connector has to be expensively integrated into the motherboard. The task of the invention is to create an electrical device of which the housing protects a circuit carrier against water and dust both without additional seals and also features in a simple layout and is simple to manufacture and install.

This problem can be resolved by an electrical device comprising a cup-shaped lower housing part with a front insertion opening, a circuit carrier, that is inserted into the lower part of the housing, a connector, and a sealing part to seal the insertion opening, that is connected to the lower part of the housing mechanically and with a hinge and features a cutout for the connector. The problem can also be solved by an electrical device comprising a cupshaped lower housing part with a front insertion opening, a circuit carrier, that is inserted into the lower part of the housing, said circuit carrier comprising a connector, and a sealing part to seal the insertion opening comprising a hinge coupled with the housing part, wherein the sealing part comprises a cutout for the connector.

The sealing part can be mechanically connected in one piece to the lower part of the housing by at least one film hinge. The sealing part may feature a first cover and a second cover, each of which has a cutout for connector and in the closed state lying against the connector supplement each other in such as way that the insertion opening is sealed. The first cover can be mechanically connected with a first side of the insertion opening of the lower part of the housing and the second cover can be mechanically connected with a second side of the insertion opening of the lower part of the housing. The first cover can be connected with one side of the insertion opening of the lower part of the housing and the second cover can be connected with the opposite side of the insertion opening of the lower part of the housing. The connector can be electrically and mechanically connected with circuit carrier. The sealing part may feature locating elements, that engage on closure into cutouts of the lower part of the housing.

Here the electrical device features a cup-shaped housing to accept a circuit carrier with a front-side insertion opening. The circuit carrier features a connector. The opening is sealed by a sealing part that features a cut-out for the connector.

The sealing part is connected to one a side of the insertion opening of the housing by a mechanical sealing flap. To seal the insertion opening, the sealing part is folded down over the insertion opening.

The cup-shaped housing of the electrical device in accordance with the invention thus has only one open side, i.e. the other sides of the housing are sealed against the intrusion of water and dust. If the housing is installed with the insertion opening pointing downwards, water coming from above of runs off the outsides of housing and the circuit arrangement remains dry.

Conventional connectors can also be used here that do not have to be expensively integrated into the sealing part.

Advantageous embodiments of the invention are described in the subclaims.

The mechanical connection between sealing part and housing can for example be designed as a film hinge. However other hinges can also be used which fulfil the requirements for sealing the housing.

When film hinges are used the housing can be manufactured with a single tool which significantly reduces the costs of manufacturing.

If the connector protrudes so far out of the housing that the sealing parked collides with the connector when it is closed, there is the option of designing the sealing part in a number of sections. The insertion opening of the housing is thus sealed by a number of complementary covers. A connector protruding from the housing has the further advantage that it needs less space on the printed circuit board.

This prevents the cutout in the sealing part being so large that the housing features at least one gap between the sealing part and the connector into which water and dust could again penetrate.

The sealing part can for example consist of at least one first and one second cover.

The first cover of the sealing part is connected via a hinge to a first side of the housing. folded across the insertion opening, the first cover covers a part of the insertion opening from a side horizontal to the attachment side up to the connector and the space between connected side and connector to the width of the connector. The areas of the insertion opening that are still open are covered by a second cover that is connected to another side of the insertion opening by a mechanical flap. The shape of the two covers is matched to the shape of the connector and to that of the insertion opening. They seal the housing in the closed state to the connector.

When the sealing part is subdivided into the individual covers it is not a matter of having the form described above. The individual covers should be formed in such a way that they can be hinged around connectors protruding from the housing and when closed, supplement a sealing part surrounding the connector, and thus seal the housing in accordance with required protection class.

### BRIEF DESCRIPTION OF THE DRAWINGS

An exemplary embodiment is explained below in more detail with reference to the schematic drawings. The figures show:

FIG. 1 a front view of the “open” electrical device in accordance with the invention,

FIG. 2 a section through the “open” electrical device along the line II-II in FIG. 1,

FIG. 3 a perspective view of the “open” electrical device without circuit carrier and connector, and

FIG. 4 the perspective view of the closed electrical device.

### DETAILLED DESCRIPTION OF THE PREFERRED EMBODIMENTS

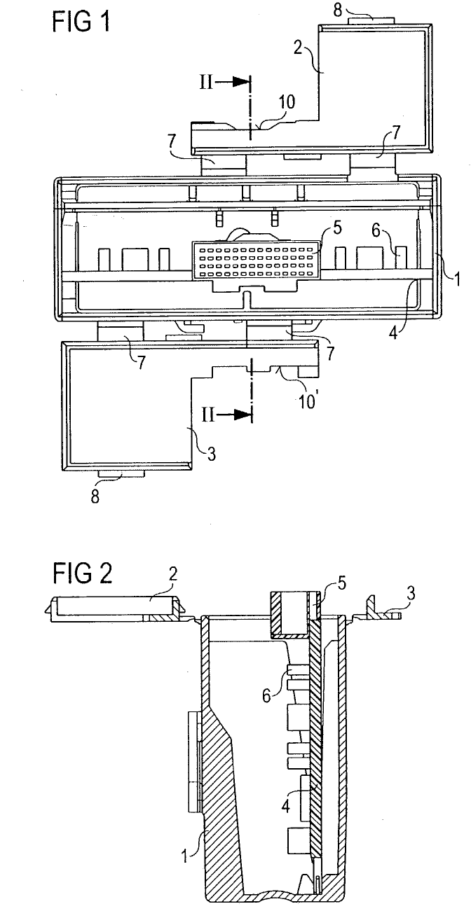

FIG. 1 shows a front view of the electrical device in accordance with the invention in the non-closed state. The electrical device features a housing, a circuit carrier 4 and a connector 5. The housing features a cup-shaped lower housing part 1 and a first cover 2 and a second cover 3. The connector 5 is connected electrically and mechanically to the circuit carrier 4 and will be inserted (when the device is installed) together with the circuit career 4 into a front insertion opening of the housing.

The first cover 2 has a hinged one-piece connection via two film hinges 7 to the wide side of the insertion opening and features a cutout 10 for connector 5. The first cover 2 also seals the area of the insertion opening from one end of the wide side up to connector 5 and, across the width of the connector, the area between this and the wide side. The second cover 3 also has a hinged mechanical connection here with the opposite wide side. The second cover 3 is also connected via two film hinges 7 with the housing and features a second cutout 10′ for connector 5. The second cover 3 seals the area of the insertion opening not sealed by the first cover 2, i.e. the area between connector 5 and wide side with which the second cover 3 is connected and the area from the end of connector 5 to the other end of the wide side. In this way covers 2 and 3 supplement each other and seal the insertion opening.

The exemplary embodiment shown in FIG. 1, in which connector 5 protrudes from housing 1, has the advantage that connector 5 requires less space on circuit carrier 4.

FIG. 2 shows a section through the electrical device and along the line II-II from FIG. 1. It also shows the electrical device in the non-closed state. A circuit carrier 4 populated with electrical components 6 is inserted into the housing. The insertion opening is covered by the closing of the first and second cover 2 and 3 of the sealing part. Covers 2 and 3 are adapted both to the lower part of the housing 1 as well as to connector 5.

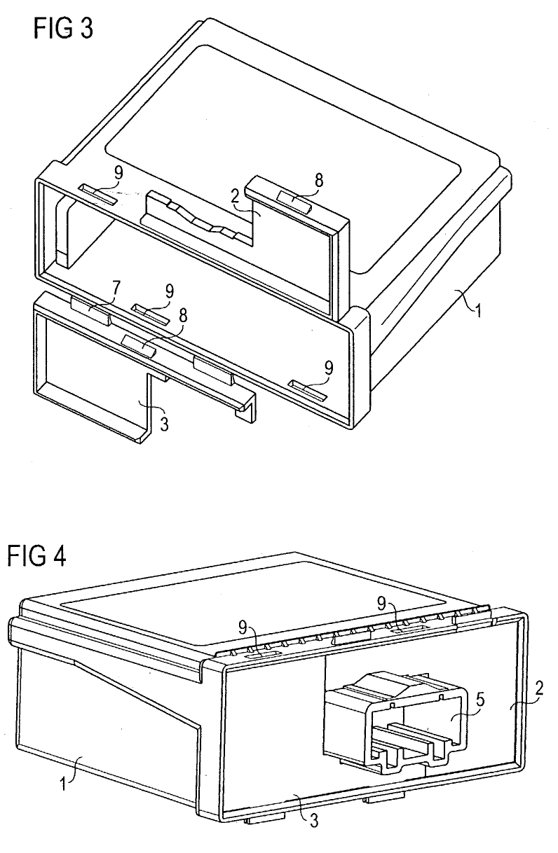

FIG. 3 shows a perspective view of the open housing.

In the exemplary embodiment the first and the second cover 2 and 3 are designed so that in their closed state they engage with a slot on the bottom part of the housing.

The sealed electrical device is shown in FIG. 4. To seal the device the first cover 2 is initially hinged down over the insertion opening and located into the opposite wide side. The first cover 2 thereby surrounds the upper wide side of connector 5 and its left narrow side, the procedure is the same with the second cover 3. This is hinged over the insertion opening and also engaged. It surrounds the lower wide side of connector 5 and its right narrow side.

In the exemplary embodiment shown here the two covers 2 and 3 have location elements 8 that engage from within into cutouts 9 in the lower housing part 1.

The device in accordance with the invention can, when it is installed with the insertion opening downwards, be used wherever an electronic circuit is to be protected from water drips and dust.

1. An electrical device comprising:
a cup-shaped lower housing part with a front insertion opening,
a circuit carrier, that is inserted into the lower part of the housing,
a connector, and
a sealing part to seal the insertion opening, that is connected to the lower part of the housing mechanically and with a hinge and features a cutout for the connector.

2. Electrical device in accordance with claim 1, wherein the sealing part is mechanically connected in one piece to the lower part of the housing by at least one film hinge.

3. Electrical device in accordance with claim 1, wherein the sealing part features a first cover and a second cover, each of which has a cutout for connector and in the closed state lying against the connector supplement each other in such as way that the insertion opening is sealed.

4. Electrical device in accordance with claim 3, wherein the first cover is mechanically connected with a first side of the insertion opening of the lower part of the housing and the second cover is mechanically connected with a second side of the insertion opening of the lower part of the housing.

5. Electrical device in accordance with claim 4, wherein the first cover is connected with one side of the insertion opening of the lower part of the housing and the second cover is connected with the opposite side of the insertion opening of the lower part of the housing.

6. Electrical device in accordance with claim 1, wherein the connector is electrically and mechanically connected with circuit carrier.

7. Electrical device in accordance with claim 1, wherein the sealing part features locating elements, that engage on closure into cutouts of the lower part of the housing.

8. An electrical device comprising:
a cup-shaped lower housing part with a front insertion opening,
a circuit carrier, that is inserted into the lower part of the housing, said circuit carrier comprising a connector, and
a sealing part to seal the insertion opening comprising a hinge coupled with the housing part, wherein the sealing part comprises a cutout for the connector.

9. Electrical device in accordance with claim 8, wherein the sealing part is mechanically connected in one piece to the lower part of the housing by at least one film hinge.

10. Electrical device in accordance with claim 8, wherein the sealing part comprises a first cover and a second cover, each of which has a cutout for connector and in the closed state lying against the connector supplement each other in such as way that the insertion opening is sealed.

11. Electrical device in accordance with claim 10, wherein the first cover is mechanically connected with a first side of the insertion opening of the lower part of the housing and the second cover is mechanically connected with a second side of the insertion opening of the lower part of the housing.

12. Electrical device in accordance with claim 11, wherein the first cover is connected with one side of the insertion opening of the lower part of the housing and the second cover is connected with the opposite side of the insertion opening of the lower part of the housing.

13. Electrical device in accordance with claim 8, wherein the connector is electrically and mechanically connected with circuit carrier.

14. Electrical device in accordance with claim 8, wherein the sealing part comprsises locating elements, that engage on closure into cutouts of the lower part of the housing.
